(19) United States
(12) Patent Application Publication
(10) Pub. No.: US 2025/0393119 A1
(43) Pub. Date: Dec. 25, 2025

(54) ANTI-WARPAGE CARRIER

(71) Applicant: KINSUS INTERCONNECT TECHNOLOGY CORP., Taoyuan City (TW)

(72) Inventors: Ting-Hao LIN, Taoyuan City (TW); Chiao-Cheng CHANG, Taoyuan City (TW); Chien-Wei CHANG, Taoyuan City (TW)

(21) Appl. No.: 18/826,338

(22) Filed: Sep. 6, 2024

(30) Foreign Application Priority Data
Jun. 20, 2024 (TW) 113122993

(51) Int. Cl. H05K 1/02; H05K 1/03; H05K 1/11

(52) U.S. Cl. CPC H05K 1/0271; H05K 1/0306; H05K 1/111; H05K 1/115

(57) ABSTRACT

An anti-warpage carrier includes a substrate, ceramic plates, metal pillars, a resin layer, and first and second circuit boards. The substrate has first through holes penetrating through an upper surface and a lower surface of the substrate. The ceramic plates are disposed on the upper surface and engaged with each other to form a ceramic plate assembly. The ceramic plate has second through holes penetrating through a first surface and a second surface of the ceramic plate. The metal pillars are respectively in the second through holes. The resin layer covers the ceramic plate assembly and the upper surface and has openings. The first circuit layer is on a portion of a surface of the resin layer, in the openings, and connected to the metal pillars. The second circuit layer is on a portion of the lower surface, in the first through holes, and connected to the metal pillars.

### CROSS-REFERENCE TO RELATED APPLICATION

This non-provisional application claims priority under 35 U.S.C. § 119(a) to patent application No. 113122993 filed in Taiwan, R.O.C. on Jun. 20, 2024, the entire contents of which are hereby incorporated by reference.

### BACKGROUND

### Technical Field

The instant disclosure is related to the field of chip packaging, especially to an anti-warpage carrier.

### Related Art

After the 2.0 D to 3.0 D packaging requirements for semiconductor chips arise, both the density and the complexity for the packaging greatly increase. To meet the packaging requirements for semiconductor chips, an interposer is introduced, and chiplets are packaged in a large-splicing manner.

However, due to the requirements of crisscross large-area splicing, the biggest challenge to advanced packaging is the flatness and stability of a material substrate, especially in the face of large temperature changes in the welding process. Currently, by increasing the thickness of a core plate, the industry can improve an assembly process, actual operation of products, and the coplanarity and stability of packaging planes. However, the core plate known to the inventor is made of glass fiber, which has the biggest disadvantage of thermal stability. As to the chiplets and large-area packaging, high coplanarity and stability are necessary characteristics. Therefore, improving the temperature resistance and mechanical strength of carriers is a major challenge today.

As known to the inventor, a glass substrate is used as the core plate, allowing the core plate to have a large dimension. However, since the thermal expansion coefficient of the glass is greatly differed from the thermal expansion coefficient of the resin material used in the core substrate known to the inventor, after the thermal process of the lamination and building-up processes are performed, the carrier may have warpage issue which will then cause plate scratch or other issues. As a result, the yield rate for packaging processes using the glass substrate as the core plate is not good.

### SUMMARY

It is found that, as known to the inventor, ceramic materials are applied to replace the glass so as to reduce the thermal expansion coefficient of the carrier to reduce the warpage issue. However, when the ceramic plate is made in a large dimension, the uniformness and the flatness of the ceramic plate are hard to meet the specification.

To address these issues, an anti-warpage carrier is provided. in some embodiments, the anti-warpage carrier comprises a substrate, a plurality of ceramic plates, a plurality of metal pillars, a resin layer, a first circuit layer, and a second circuit layer. The substrate has an upper surface and a lower surface, and the substrate has a plurality of first through holes penetrating through the upper surface and the lower surface. The ceramic plates are disposed on the upper surface of the substrate and are engaged with each other to form a ceramic plate assembly. The ceramic plates have a plurality of second through holes, and each of the second through holes penetrates through a first surface and a second surface of a corresponding one of the ceramic plates.

The metal pillars are respectively in the second through holes. The resin layer is on the upper surface of the substrate and the ceramic plate assembly. The resin layer covers the ceramic plates and the upper surface of the substrate. The resin layer has a plurality of openings. The first circuit layer is on a portion of a surface of the resin layer and in the openings, and the first circuit layer is connected to the metal pillars. The second circuit layer is on a portion of the lower surface of the substrate and in the first through holes, and the second circuit layer is connected to the metal pillars.

In some embodiments, each of the ceramic plates comprises a recess and a protrusion, and the recess of each of the ceramic plates is engaged with the protrusion of a ceramic plate adjacent thereto.

In some embodiments, each of the ceramic plates comprises a plurality of recesses, and the anti-warpage carrier further comprises a plurality of ceramic engaging members; in the ceramic plate assembly, the recesses of adjacent ceramic plates are opposite to each other to form a plurality of engaging grooves, the ceramic engaging members are disposed in the engaging grooves, so that the ceramic plates are engaged with each other.

In some embodiments, the anti-warpage carrier further comprises a protection adhesive layer, and the protection adhesive layer is disposed on a portion of an outer peripheral surface of the ceramic plate assembly.

In some embodiments, positions of the openings correspond to positions of the second through holes, respectively.

In some embodiments, the first surface of each of the ceramic plates is further provided with a third circuit layer, and the third circuit layer is connected to the metal pillars in the second through holes and the first circuit layer.

In some embodiments, the second surface of each of the ceramic plates is further provided with a fourth circuit layer, and the fourth circuit layer is connected to the metal pillars in the second through holes and the second circuit layer.

In some embodiments, the anti-warpage carrier further comprises a first solder mask layer, a first bonding pad layer, a second solder mask layer, and a second bonding pad layer. The first solder mask layer is on the resin layer and has a plurality of first bonding pad openings, and the first bonding pad layer is in the first bonding pad openings and electrically connected to the first circuit layer. The second solder mask layer is on the lower surface of the substrate and has a plurality of second bonding pad openings, and the second bonding pad layer is in the second bonding pad openings and electrically connected to the second circuit layer. The first bonding pad layer comprises a plurality of first bonding pads protruding out of the first solder mask layer, the second bonding pad layer comprises a plurality of second bonding pads protruding out of the second solder mask layer, and a first pitch between the first bonding pads is less than a second pitch between the second bonding pads.

Specifically, in some embodiments, the anti-warpage carrier further comprises a first protection layer, a first redistribution layer, a second protection layer, and a second redistribution layer. The first protection layer is between the resin layer and the first solder mask layer, and the first protection layer covers the first circuit layer and has a plurality of first openings. The first redistribution layer is on a portion of the first protection layer and is in the first openings, and the first redistribution layer is connected to the first circuit layer and the first solder mask layer. The second protection layer is between the lower surface of the substrate and the second solder mask layer, and the second protection layer covers the second circuit layer and has a plurality of second openings. The second redistribution layer is on a portion of the second protection layer and is in the second openings, and the second redistribution layer is connected to the second circuit layer and the second solder mask layer.

In some embodiments, positions of the first openings correspond to positions of the first bonding pad openings, respectively, and positions of the second openings correspond to positions of the second bonding pad openings, respectively.

According to one or some embodiments, by using the ceramic plates to enhance the temperature-resistant property and the mechanical strength of the entire carrier, the difference between the thermal expansion coefficient of the carrier and the thermal expansion coefficient of the resin material can be further reduced. Moreover, in some embodiments, the ceramic plates are assembled as a ceramic plate assembly in a splicing manner, so that the issues occurred in manufacturing large-dimension ceramic plates can be addressed, thereby allowing the anti-warpage carrier to be applied in large-dimension advanced packaging technologies.

### BRIEF DESCRIPTION OF THE DRAWINGS

The disclosure will become more fully understood from the detailed description given herein below for illustration only, and thus not limitative of the disclosure, wherein:

FIG. 1 illustrates a partial top view of an anti-warpage carrier according to a first embodiment of the instant disclosure;

FIG. 2 illustrates a partial cross-sectional view of the anti-warpage carrier according to the first embodiment of the instant disclosure;

FIG. 3 illustrates a partial top view of an anti-warpage carrier according to a second embodiment of the instant disclosure;

FIG. 4 illustrates a partial top view of an anti-warpage carrier according to a third embodiment of the instant disclosure;

FIG. 5 illustrates a partial top view of an anti-warpage carrier according to a fourth embodiment of the instant disclosure;

FIG. 6 illustrates a partial top view of an anti-warpage carrier according to a fifth embodiment of the instant disclosure; and

FIG. 7 illustrates a partial cross-sectional view of an anti-warpage carrier according to a sixth embodiment of the instant disclosure.

### DETAILED DESCRIPTION

It should be understood that, when an element is referred to as being “disposed on” or “connected to” another element, the element may be directly on the another element, or one or more intervening elements may be present so that the element is connected to the another element through the one or more intervening elements. On the contrary, when an element is referred to as being “directly disposed on/directly connected on” or “directly disposed to/directly connected to” another element, it can be clearly understood that there are no intervening elements between the two elements.

Furthermore, in the following descriptions, it will be understood that, although the terms “first,” “second,” “third,” etc. may be used herein to describe various elements, components, regions, layers, or portions, these terms are only used to distinguish these elements, components, regions, layers, or sections, rather than being used to represent the definite order of these elements, components, regions, layers, or portions. Moreover, it will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. In other words, these terms only represent a relative position relationship between the described components, not an absolute position relationship between the described components.

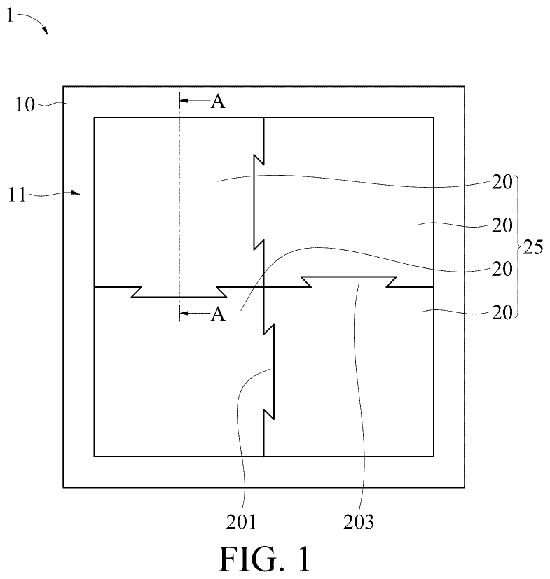

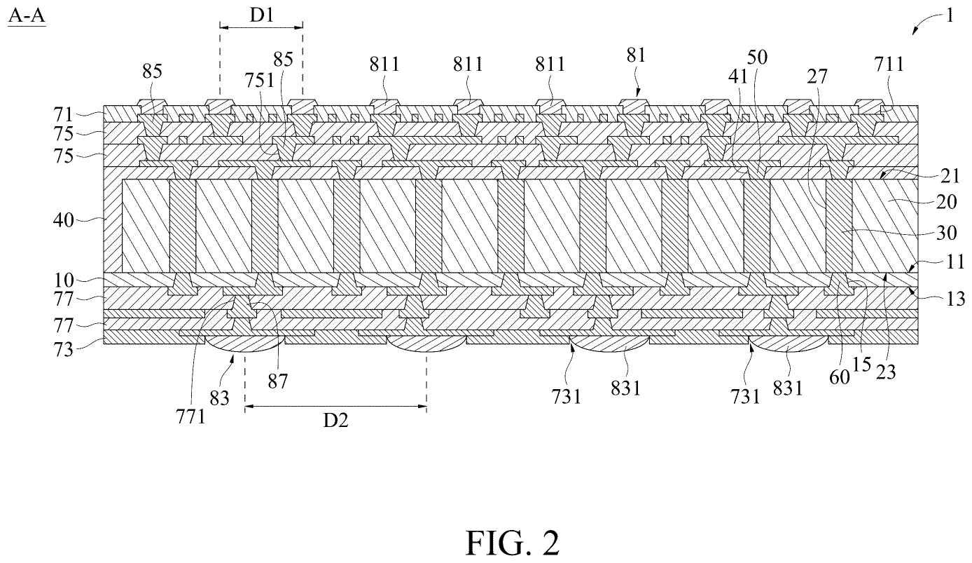

FIG. 1 illustrates a partial top view of an anti-warpage carrier according to a first embodiment of the instant disclosure. FIG. 2 illustrates a partial cross-sectional view of the anti-warpage carrier according to the first embodiment of the instant disclosure. FIG. 2 illustrates a cross-sectional view along line A-A shown in FIG. 1. As shown in FIG. 1 and FIG. 2, in some embodiments, the anti-warpage carrier 1 comprises a substrate 10, a plurality of ceramic plates 20, a plurality of metal pillars 30, a resin layer 40, a first circuit layer 50, a second circuit layer 60. The substrate 10 has an upper surface 11 and a lower surface 13. The substrate 10 has a plurality of first through holes 15 penetrating through the upper surface 11 and the lower surface 13.

To illustrate the overall structure of the anti-warpage carrier 1, in FIG. 1, the metal pillars 30, the resin layer 40, the first circuit layer 50, and the second circuit layer 60 are omitted. As shown in FIG. 1, the ceramic plates 20 are disposed on the upper surface 11 of the substrate 10, and the ceramic plates 20 are engaged with each other to form a ceramic plate assembly 25. Further, as shown in FIG. 2, the ceramic plates 20 have a plurality of second through holes 27, and each of the second through holes 27 penetrates through a first surface 21 and a second surface 23 of a corresponding one of the ceramic plates 20. The metal pillars 30 are respectively in the second through holes 27. The resin layer 40 is on the upper surface 11 of the substrate 10 and the ceramic plate assembly 25, the resin layer 40 covers the ceramic plates 20 and the upper surface 11 of the substrate 10, and the resin layer 40 has a plurality of openings 41. The first circuit layer 50 is on a portion of a surface of the resin layer 40 and in the openings 41, and the first circuit layer 50 is connected to the metal pillars 30. The second circuit layer 60 is on a portion of the lower surface 13 of the substate 10 and in the first through holes 15, and the second circuit layer 60 is connected to the metal pillars 30.

Please refer to FIG. 1 again. In the first embodiment, each of the ceramic plates 20 comprises a recess 201 and a protrusion 203 which are approximately formed as rectangular structures. The protrusion 203 of one of the two adjacent ceramic plates 20 is engaged with the recess 201 of the other one of the two adjacent ceramic plates 20, so that the ceramic plates 20 are engaged with each other like jigsaws to form the ceramic plate assembly 25. However, it is understood that, the embodiments are provided for illustrative purposes, not limitations to the instant disclosure.

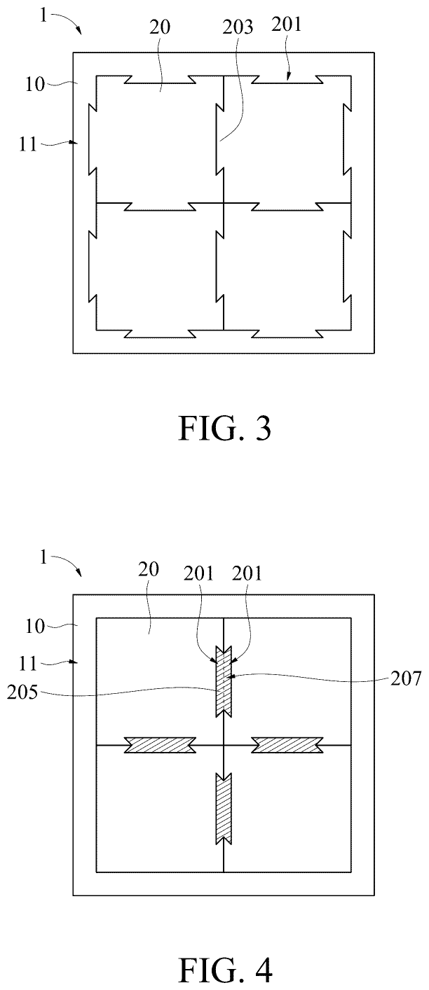

FIG. 3 illustrates a partial top view of an anti-warpage carrier according to a second embodiment of the instant disclosure. Likewise, to illustrate the overall structure of the anti-warpage carrier 1, in FIG. 3, the metal pillars 30, the resin layer 40, the first circuit layer 50, and the second circuit layer 60 are omitted. Please refer to FIG. 3 and also FIG. 1. The difference between the second embodiment and the first embodiment lies in that, in the second embodiment, each of the ceramic plates 20 comprises two recesses 201 and two protrusions 203. Therefore, the ceramic plates 20 can be assembled with each other in any orientation, allowing the ceramic plates 20 to provide a higher assembling efficiency.

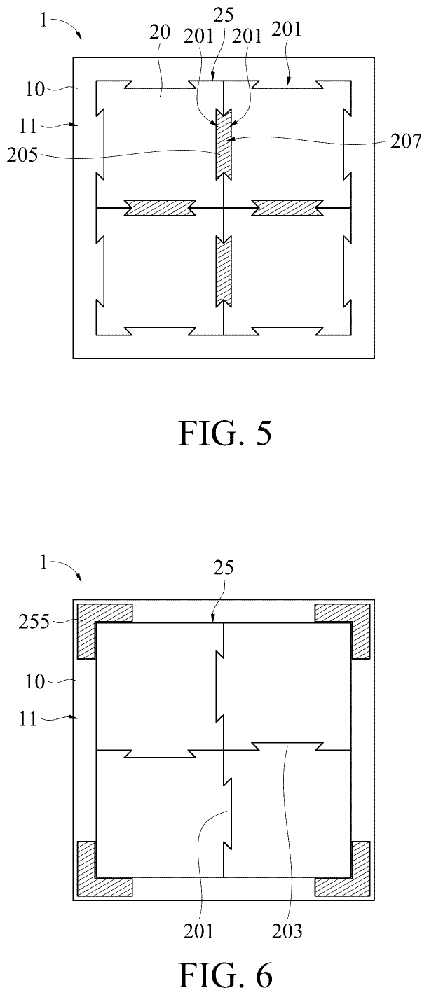

FIG. 4 illustrates a partial top view of an anti-warpage carrier according to a third embodiment of the instant disclosure. FIG. 5 illustrates a partial top view of an anti-warpage carrier according to a fourth embodiment of the instant disclosure. Likewise, to illustrate the overall structure of the anti-warpage carrier 1, in FIG. 4 and FIG. 5, the metal pillars 30, the resin layer 40, the first circuit layer 50, and the second circuit layer 60 are omitted. Please refer to FIG. 4 and FIG. 5 and also FIG. 3 and FIG. 1. The difference between the third embodiment/the fourth embodiment and the second embodiment/the first embodiment lies in that, in the third embodiment and the fourth embodiment, the ceramic plate 20 only comprises the recess 201 and does not comprise the protrusion 203. In these embodiments, the anti-warpage carrier 1 further comprises a plurality of ceramic engaging members 205, so that the ceramic plates 20 are engaged with each other using the ceramic engaging members 205. Upon forming the ceramic plate assembly 25, the recesses 201 of adjacent ceramic plates 20 are opposite to each other to form a plurality of engaging grooves 207, and the ceramic engaging members 205 are disposed in the engaging grooves 207, so that the ceramic plates 20 are engaged with each other.

FIG. 6 illustrates a partial top view of an anti-warpage carrier according to a fifth embodiment of the instant disclosure. Likewise, to illustrate the overall structure of the anti-warpage carrier 1, in FIG. 6, the metal pillars 30, the resin layer 40, the first circuit layer 50, and the second circuit layer 60 are omitted. Please refer to FIG. 6 and also FIG. 1, FIG. 3, FIG. 4, and FIG. 5. The anti-warpage carrier 1 further comprises a protection adhesive layer 255, and the protection adhesive layer 255 is disposed on a portion of an outer peripheral portion of the ceramic plate assembly 25. For example, the protection adhesive layer 255 may be disposed on four corners of the ceramic plate assembly 25 or fully encloses the outer peripheral portion of the ceramic plate assembly 25. Therefore, upon an external force is applied to the ceramic plate assembly 25, the protection adhesive layer 255 can provide a buffer effect to prevent the ceramic plates 20 from being broken. In this embodiment, as shown in FIG. 6, the protection adhesive layer 255 is disposed at and encloses the four corners of the ceramic plate assembly 25 shown in FIG. 1. However, it is understood that, the embodiments are provided for illustrative purposes, not limitations to the instant disclosure. moreover, in some embodiments, the protection adhesive layer 255 may be formed on the ceramic plate assembly 25 upon forming the resin layer 40.

Please refer to FIG. 2 again. In some embodiments, positions of the openings 41 may correspond to positions of the second through holes 27, respectively. Specifically, in some embodiments, the anti-warpage carrier 1 further comprises a first solder mask layer 71, a first bonding pad layer 81, a second solder mask layer 73, and a second bonding pad layer 83. The first solder mask layer 71 is on the resin layer 40 and has a plurality of first bonding pad openings 711. The first bonding pad layer 81 is in the first bonding pad openings 711 and electrically connected to the first circuit layer 50. The second solder mask layer 73 is on the lower surface 13 of the substrate 10 and has a plurality of second bonding pad openings 731. The second bonding pad layer 83 is in the second bonding pad openings 731 and electrically connected to the second circuit layer 60. The first bonding pad layer 81 comprises a plurality of first bonding pads 811 protruding out of the first solder mask layer 71. The second bonding pad layer 83 comprises a plurality of second bonding pads 831 protruding out of the second solder mask layer 73, and a first pitch D1 between the first bonding pads 811 is less than a second pitch D2 between the second bonding pads 831.

Specifically, in some embodiments, the anti-warpage carrier 1 further comprises a first protection layer 75, a first redistribution layer 85, a second protection layer 77, and a second redistribution layer 87. The first protection layer 75 is between the resin layer 40 and the first solder mask layer 71, and the first protection layer 75 covers the first circuit layer 50 and has a plurality of first openings 751. The first redistribution layer 85 is on a portion of the first protection layer 75 and is in the first openings 751, and the first redistribution layer 85 is connected to the first circuit layer 50 and the first solder mask layer 81. The second protection layer 77 is between the lower surface 13 of the substrate 10 and the second solder mask layer 73, and the second protection layer 77 covers the second circuit layer 60 and has a plurality of second openings 771. The second redistribution layer 87 is on a portion of the second protection layer 77 and is in the second openings 771, and the second redistribution layer 87 is connected to the second circuit layer 60 and the second solder mask layer 83.

More specifically, in some embodiments, positions of the first openings 751 correspond to positions of the first bonding pad openings 711, respectively, and positions of the second openings 771 correspond to positions of the second bonding pad openings 731, respectively. In this embodiment, the first protection layer 75, the first redistribution layer 85, the second protection layer 76, and the second redistribution layer 87 may be configured as one or several layers to be adapted to the layouts.

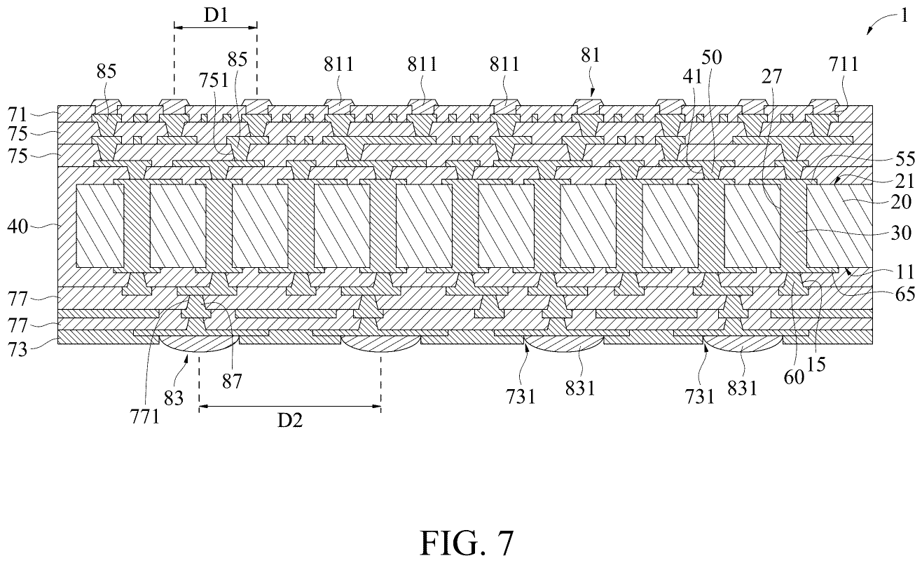

FIG. 7 illustrates a partial cross-sectional view of an anti-warpage carrier according to a sixth embodiment of the instant disclosure. Please refer to FIG. 7 and also FIG. 2. In the sixth embodiment, the first surface 21 of each of the ceramic plates 20 is further provided with a third circuit layer 55, and the third circuit layer 55 is connected to the metal pillars 30 in the second through holes 27 and the first circuit layer 50.

Moreover, in some embodiments, the second surface 23 of each of the ceramic plates 20 is further provided with a fourth circuit layer 65, and the fourth circuit layer 65 is connected to the metal pillars 30 in the second through holes 27 and the second circuit layer 60.

According to one or some embodiments, by using the ceramic plates 20 to enhance the temperature-resistant property and the mechanical strength of the entire of the anti-warpage carrier 1, the difference between the thermal expansion coefficient of the carrier and the thermal expansion coefficient of the resin material can be further reduced. Moreover, in some embodiments, the ceramic plates 20 are assembled as a ceramic plate assembly 25 in a splicing manner, so that the issues occurred in manufacturing large-dimension ceramic plates can be addressed, thereby allowing the anti-warpage carrier to be applied in large-dimension advanced packaging technologies.

Although the instant disclosure has been disclosed as above by way of embodiments, the embodiments are not intended to limit the scope of the instant disclosure, and persons having ordinary skills in the art may make some changes and modifications without departing from the spirit and scope of the instant disclosure, and therefore the scope of protection of the instant disclosure shall be subject to the scope of the instant disclosure as defined in the appended claims.

What is claimed is:

1. An anti-warpage carrier comprising:
a substrate having an upper surface and a lower surface, wherein the substrate has a plurality of first through holes penetrating through the upper surface and the lower surface;
a plurality of ceramic plates disposed on the upper surface of the substrate, wherein the ceramic plates are engaged with each other to form a ceramic plate assembly, the ceramic plates have a plurality of second through holes, and each of the second through holes penetrates through a first surface and a second surface of the corresponding one of the ceramic plates;
a plurality of metal pillars in the second through holes, respectively;
a resin layer on the upper surface of the substrate and the ceramic plate assembly, wherein the resin layer covers the ceramic plates and the upper surface of the substrate, and the resin layer has a plurality of openings;
a first circuit layer on a portion of a surface of the resin layer and in the openings, wherein the first circuit layer is connected to the metal pillars; and
a second circuit layer on a portion of the lower surface of the substrate and in the first through holes, wherein the second circuit layer is connected to the metal pillars.

2. The anti-warpage carrier according to claim 1, wherein each of the ceramic plates comprises a recess and a protrusion, and the recess of each of the ceramic plates is engaged with the protrusion of a ceramic plate adjacent thereto.

3. The anti-warpage carrier according to claim 1, wherein each of the ceramic plates comprises a plurality of recesses, and the anti-warpage carrier further comprises a plurality of ceramic engaging members; in the ceramic plate assembly, the recesses of adjacent ceramic plates are opposite to each other to form a plurality of engaging grooves, the ceramic engaging members are disposed in the engaging grooves, so that the ceramic plates are engaged with each other.

4. The anti-warpage carrier according to claim 1 further comprising a protection adhesive layer, wherein the protection adhesive layer is disposed on a portion of an outer peripheral portion of the ceramic plate assembly.

5. The anti-warpage carrier according to claim 1, wherein positions of the openings correspond to positions of the second through holes, respectively.

6. The anti-warpage carrier according to claim 1, wherein the first surface of each of the ceramic plates is further provided with a third circuit layer, and the third circuit layer is connected to the metal pillars in the second through holes and the first circuit layer.

7. The anti-warpage carrier according to claim 6, wherein the second surface of each of the ceramic plates is further provided with a fourth circuit layer, and the fourth circuit layer is connected to the metal pillars in the second through holes and the second circuit layer.

8. The anti-warpage carrier according to claim 1 further comprising a first solder mask layer, a first bonding pad layer, a second solder mask layer, and a second bonding pad layer, wherein the first solder mask layer is on the resin layer and has a plurality of first bonding pad openings, and the first bonding pad layer is in the first bonding pad openings and electrically connected to the first circuit layer; the second solder mask layer is on the lower surface of the substrate and has a plurality of second bonding pad openings, and the second bonding pad layer is in the second bonding pad openings and electrically connected to the second circuit layer; the first bonding pad layer comprises a plurality of first bonding pads protruding out of the first solder mask layer, the second bonding pad layer comprises a plurality of second bonding pads protruding out of the second solder mask layer, and a first pitch between the first bonding pads is less than a second pitch between the second bonding pads.

9. The anti-warpage carrier according to claim 8 further comprising a first protection layer, a first redistribution layer, a second protection layer, and a second redistribution layer, wherein the first protection layer is between the resin layer and the first solder mask layer, and the first protection layer covers the first circuit layer and has a plurality of first openings; the first redistribution layer is on a portion of the first protection layer and is in the first openings, and the first redistribution layer is connected to the first circuit layer and the first solder mask layer; the second protection layer is between the lower surface of the substrate and the second solder mask layer, and the second protection layer covers the second circuit layer and has a plurality of second openings; the second redistribution layer is on a portion of the second protection layer and is in the second openings, and the second redistribution layer is connected to the second circuit layer and the second solder mask layer.

10. The anti-warpage carrier according to claim 9, wherein positions of the first openings correspond to positions of the first bonding pad openings, respectively, and positions of the second openings correspond to positions of the second bonding pad openings, respectively.
